(19) United States
(12) Patent Application Publication
(10) Pub. No.: US 2026/0352213 A1
(43) Pub. Date: Nov. 5, 2026

(54) DYNAMIC VOLTAGE LEVEL TRANSLATION INTERFACE

(71) Applicant: Western Digital Technologies, Inc., San Jose, CA (US)

(72) Inventors: Diego Maffei, Tustin, CA (US); Zabih Toosky, San Marcos, CA (US); John T. Contreras, Palo Alto, CA (US); Rehan Zakai, San Ramon, CA (US)

(73) Assignee: Western Digital Technologies, Inc., San Jose, CA (US)

(21) Appl. No.: 19/194,124

(22) Filed: Apr. 30, 2025

(51) Int. Cl. H03K 19/0185; G05F 1/575; G05F 3/26

(52) U.S. Cl. CPC H03K 19/018507; G05F 1/575; G05F 3/262

(57) ABSTRACT

A dynamic voltage level translation interface allows a second circuit component to operate within a secondary voltage domain referenced to a floating substrate potential and to communicate with a first circuit component operating within a primary voltage domain. A substrate tracking regulator generates a supply voltage that is dynamically tracked relative to the floating substrate potential and supplied to the second circuit component. A voltage level translator shifts voltage levels between the secondary and primary voltage domains to enable communication therebetween. The substrate tracking regulator includes a bandgap circuit that generates a bandgap voltage independent of the floating substrate potential, and an LDO regulator that regulates the supply voltage at a stable offset from the floating substrate potential.

### BACKGROUND

Modern integrated circuit (IC) design often incorporates pre-designed circuit components or blocks that perform specific functions, such as logic operations, memory storage, signal processing, power management, clock generation, timing control, and other functions. These pre-designed circuit components may be organized into intellectual property (IP) libraries, where each standardized circuit component, referred to as an IP cell, can be integrated into a larger IC design with little or no modification. Rather than designing every circuit component of an IC from scratch, designers can incorporate IP cells into larger systems. The ability to reuse IP cells across different ICs and manufacturing processes has made them a cornerstone of modern IC design.

While IP cells are typically designed to be as process-compatible and reusable as possible, design constraints and application-specific requirements may sometimes exist that limit their direct use. One such challenge arises in ICs that operate with a negatively biased substrate, which can complicate the integration of IP cells designed using complementary metal-oxide-semiconductor (CMOS) technology. In disk drive ICs, for example, a negative substrate bias may be used for various purposes, such as enhancing electrostatic discharge (ESD) protection, improving signal integrity, preventing write head saturation, increasing signal-to-noise ratio (SNR), and facilitating generation of other required voltages within the disk drive system. Because NMOS transistors rely on a substrate connection to ground as a stable reference, integrating CMOS IP cells into an IC with a negative substrate bias presents challenges.

In a grounded substrate environment, the source, drain, and gate voltages of transistors are referenced to a fixed ground potential, making it straightforward to establish predictable voltage differentials for device operation. However, in a negatively biased substrate environment, the substrate is actively driven to a potential below ground (e.g., −2V or −3V), such that all voltages referenced to it must shift accordingly. This necessitates generation of a stable offset voltage to ensure that transistors continue to function within their intended operating ranges. For example, if a transistor is designed to operate with a supply voltage of 1.8V in a standard ground-referenced environment, it must still receive the same 1.8V supply voltage differential even when its substrate is negatively biased at −2V. In a negatively biased state, the substrate is considered to be “floating” because its potential is not inherently fixed to a stable reference like ground; rather, it fluctuates based on factors such as external biasing circuits, charge accumulation, and variations in operating conditions. If the supply voltage does not track these fluctuations, circuits referenced to the substrate may not operate properly.

One approach that has enabled use of CMOS IP cells in a negatively biased substrate environment is to create an electrically isolated region using a deep N-well (DNWELL). In this approach, a localized P-well is formed within the DNWELL, allowing NMOS transistors to be biased independently of the global (negative) substrate potential. The DNWELL is biased to a high potential (e.g., VDD) to electrically isolate it from the negatively biased substrate, while the P-well inside the DNWELL is biased to a lower potential (e.g., ground) to ensure proper NMOS transistor operation by maintaining the expected source-to-substrate voltage differential. However, the formation of DNWELL regions requires additional layout area to meet Foundry requirement as well as the required extra tap connection to it.

The inclusion of any information in this background section should not be construed as an admission that such information constitutes prior art. This background section may describe aspects of the subject invention and related concepts.

### SUMMARY

The following summary relates to one or more aspects or embodiments disclosed herein. It is not intended to provide a comprehensive overview of all contemplated aspects or embodiments, nor should it be construed as identifying key or essential features limiting the scope of any particular aspect or embodiment. Rather, this summary presents certain concepts in a simplified form as a prelude to the detailed description that follows.

One aspect of this disclosure is a method for enabling circuit components to operate within and communicate across different voltage domains. The method comprises providing a first supply voltage referenced to ground to operate a first circuit component within a primary voltage domain; providing a second supply voltage that is dynamically tracked relative to a floating substrate potential to operate a second circuit component within a secondary voltage domain; and translating voltage levels between the primary voltage domain and the secondary voltage domain to facilitate communication between the first circuit component and the second circuit component.

In some implementations, providing the second supply voltage comprises generating a bandgap voltage independent of the floating substrate potential using a bandgap circuit.

In some implementations, providing the second supply voltage further comprises regulating the second supply voltage using a low dropout (LDO) regulator.

In some implementations, the second supply voltage is VEE+VREF, the floating substrate potential is VEE, the reference voltage is VREF=Vbg*(R9/R3), Vbg is the bandgap voltage, R3 is a resistor within the bandgap circuit that references the bandgap voltage Vgb to ground, and R9 is a resistor within the LDO regulator that references the reference voltage VREF to the floating substrate potential VEE.

In some implementations, generating the bandgap voltage comprises generating a first current referenced to the floating substrate potential, the first current having a negative temperature-dependent voltage component and a positive temperature-dependent voltage component; generating a second current that is equal to the first current and that is referenced to the floating substrate potential; generating a third current that is equal to the second current and that is referenced to a voltage at least as high as the first supply voltage; and generating the bandgap voltage from the third current that is referenced to ground.

In some implementations, regulating the second supply voltage further comprises controlling an output pass transistor using a high gain amplifier in a negative feedback configuration to maintain the second supply voltage at a stable offset from the floating substrate potential.

In some implementations, regulating the second supply voltage further comprises isolating the output pass transistor from load transients and variations in the floating substrate potential using a cascode transistor.

Another aspect of this disclosure is a dynamic voltage level translation interface for enabling a second circuit component to operate within a secondary voltage domain referenced to a floating substrate potential and to communicate with a first circuit component operating within a primary voltage domain referenced to ground potential. The interface comprises a substrate tracking regulator configured to generate a supply voltage that is dynamically tracked relative to the floating substrate potential and that is supplied to the second circuit component, and a voltage level translator configured to shift voltage levels from the secondary voltage domain to the primary voltage domain to enable the second circuit component to communicate with the first circuit component.

A further aspect of this disclosure is an integrated circuit comprising a first circuit component operating within a primary voltage domain referenced to ground; a second circuit component operating within a secondary voltage domain referenced to a floating substrate potential; a substrate tracking regulator configured to generate a supply voltage dynamically tracked relative to the floating substrate potential to power the second circuit component; and a voltage level translation interface configured to translate voltage levels between the primary voltage domain and the secondary voltage domain.

These and additional aspects of this disclosure are described in greater detail below and are illustrated in the accompanying drawing figures.

### BRIEF DESCRIPTION OF THE DRAWINGS

The following description and accompanying drawings illustrate various features and advantages of this disclosure. The drawings are not necessarily to scale, as emphasis is placed on illustrating the principles of the disclosure. Like reference characters may be used to indicate the same components across different figures and views. The drawings provide illustrative examples and should not be construed as limiting the scope of this disclosure.

FIG. 1 is a conceptual block diagram of an exemplary circuit architecture comprising multiple circuit blocks operating across different voltage domains within an integrated circuit (IC), according to aspects of this disclosure.

FIG. 2 is a flow diagram of a method enabling circuit components to operate within and communicate across different voltage domains, according to aspects of this disclosure.

FIG. 3 is a conceptual block diagram of an exemplary circuit architecture illustrating the voltage-level translation interface of FIG. 1 in more detail, according to aspects of this disclosure.

FIG. 4 is a conceptual block diagram of a bandgap circuit of the substrate tracking regulator of FIG. 3, according to aspects of this disclosure.

FIG. 5 is a more detailed circuit diagram of the bandgap circuit of FIG. 4, according to aspects of this disclosure.

FIG. 6 is a flow diagram of a method for generating a bandgap reference voltage, according to aspects of this disclosure.

FIG. 7 is a circuit diagram of the LDO regulator of the substrate tracking regulator of FIG. 3, according to aspects of this disclosure.

FIG. 8A is a circuit diagram of an exemplary CMOS inverter circuit, according to aspects of this disclosure.

FIG. 8B is a conceptual IC layout of an inverter corresponding to the CMOS inverter circuit of FIG. 8A that is implemented using DNWELL isolation techniques, according to aspects of this disclosure.

FIG. 8C is a conceptual IC layout of an inverter corresponding to the CMOS inverter of FIG. 8A that is implemented using the voltage-level translation interface of FIGS. 1 and 3, according to aspects of this disclosure.

### DETAILED DESCRIPTION

The embodiments described herein are not intended to limit the invention to the precise forms disclosed, nor are they exhaustive. Rather, various embodiments are provided to facilitate understanding by those skilled in the art. The terms ‘exemplary’ and ‘example,’ as used herein, refer to instances or illustrations and should not be construed as limiting or as indicating a preferred or advantageous embodiment relative to other embodiments.

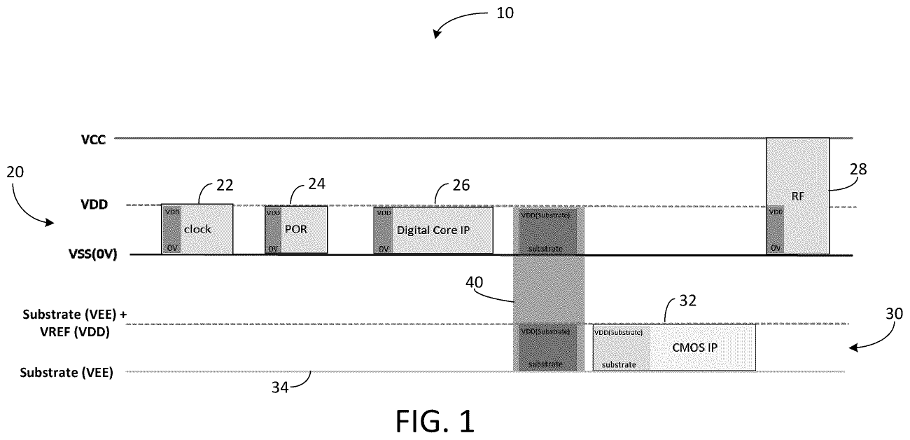

FIG. 1 is a conceptual block diagram of an exemplary circuit architecture 10 comprising multiple circuit blocks or components operating across different voltage domains within an integrated circuit (IC), according to aspects of this disclosure. In this description, standardized circuit components such as those of FIG. 1 that perform specific functions and that can be integrated into larger IC designs with little or no modification may be referred to as intellectual (IP) cells, blocks, components, or cores. IP cells typically perform defined functions that are repeatable across multiple ICs and applications, such as logic operations, memory storage, signal processing, power management, clock generation, timing control, and other functions. These standardized circuit components are organized into IP libraries, enabling their efficient reuse across different ICs and manufacturing processes.

Circuit architecture 10 is merely one example of a circuit architecture in which multiple circuit components operate within and communicate across multiple voltage domains. Circuit architecture 10 may be implemented in a variety of semiconductor applications, such as a system-on-chip (SoC), application-specific integrated circuit (ASIC), or any another IC where different circuit components operate across different voltage domains. In the specific example of FIG. 1, circuit architecture 10 comprises clock circuit component 22, power-on reset (POR) circuit component 24, digital core circuit component 26, and RF circuit component 28, which operate within primary ground-referenced voltage domain 20, and complementary metal-oxide-semiconductor (CMOS) circuit component 32, which operates within secondary voltage domain 30 established by non-ground biased substrate 34.

Non-ground referenced substrates, such as negatively biased substrate 34, may be used in ICs for various purposes. In disk drive ICs, for example, a negative substrate bias may be used to enhance electrostatic discharge (ESD) protection, improve signal integrity, prevent write head saturation, increase the signal-to-noise ratio (SNR), and facilitate the generation of other required system voltages. While a negatively biased substrate can provide design advantages in these and other applications, it may also introduce challenges, particularly for CMOS-based circuits. The NMOS transistors within a CMOS IP cell such as CMOS circuit component 32, for example, typically rely on a substrate connection to ground as a stable reference. Aspects of this disclosure address this issue by providing dynamic voltage level translation interface 40 that allows IP cells such as CMOS circuit component 32 to operate within secondary voltage domain 30 while still maintaining compatibility with IP cells such as circuit components 22, 24, 26, 28 operating within primary voltage domain 20.

In the example of FIG. 1, primary voltage domain 20 is referenced to ground (VSS=0V). Some components operating within primary voltage domain 20—such as clock cell 22, POR cell 24, and digital core IP cell 26—operate between ground and a positive supply voltage VDD. Other components, such as RF cell 28, operate between ground and a higher positive supply voltage VCC. Secondary voltage domain 30 is referenced to non-ground substrate potential 34, which in the example of FIG. 1 is negatively-biased substrate potential VEE.

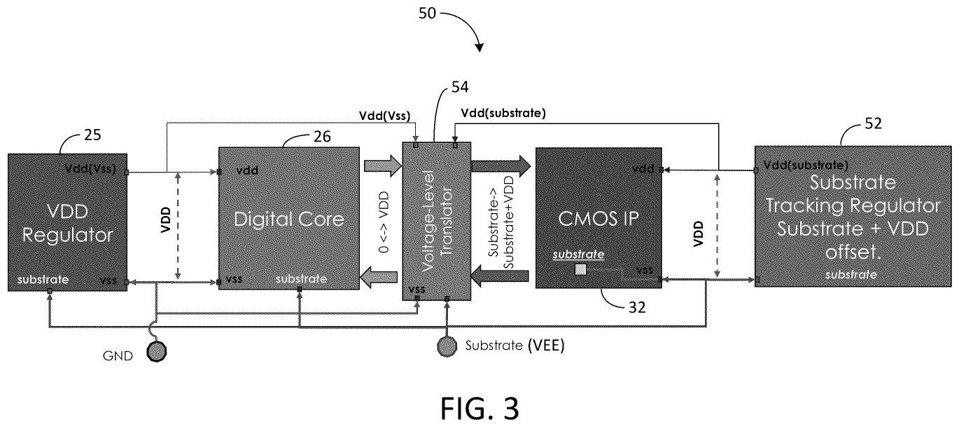

CMOS circuit component 32 operates within secondary voltage domain 30, with its supply voltage VDD defined relative to substrate potential VEE rather than ground. In this context, voltage-level translation interface 40 generates a voltage offset VREF that is referenced to VEE. In the specific examples of FIGS. 1 and 3, VREF is equal to the supply voltage VDD, but is referenced to VEE rather than to ground. In the following description, while VDD and VREF may be used interchangeably, it should be understood that VDD is just one example of a value that may be established for VREF. Additionally, while challenges associated with negatively biased substrates such as substrate 34 serve as a primary motivation, the principles disclosed herein apply broadly to any circuit component or IP cell operating within a voltage domain referenced to a non-zero potential (i.e., any potential other than ground).

Previous approaches have integrated circuit components such as CMOS IP cell 32 into negatively biased substrate environments by use of deep N-well (DNWELL) isolation techniques. A localized and electrically isolated P-well is formed within a DNWELL, allowing NMOS transistors to be biased independently of the global (negative) substrate potential. The DNWELL is biased to a high potential (e.g., VDD) to electrically isolate it from the negatively biased substrate, while the P-well inside the DNWELL is biased to a lower potential (such as ground) to ensure proper NMOS transistor operation by maintaining the expected source-to-substrate voltage differential. However, the formation of DNWELL regions requires additional layout area, as the DNWELL must be surrounded by guard rings to provide adequate electrical isolation. The guard rings must tap both the DNWELL and the enclosed P-well, further increasing the required chip area and design complexity.

Aspects of this disclosure provide an alternative approach that eliminates the need for DNWELL isolation while still enabling circuit components such as CMOS IP cell 32 to operate reliably within secondary voltage domain 30. Specifically, circuit architecture 10 comprises voltage-level translation interface 40, which allows CMOS circuit component 32 to operate within secondary voltage domain 30 without modification while still being able to communicate and interface with circuit components 22, 24, 26, 28 operating in primary voltage domain 20. Voltage-level translation interface 40 provides a stable supply voltage VREF to CMOS circuit component 32 that is referenced to floating substrate potential VEE. Floating substrate potential VEE must be dynamically tracked so that a consistent supply voltage VREF can be provided. In the specific examples of FIGS. 1 and 3, VREF is equal to the supply voltage VDD. In addition, voltage-level translation interface 40 translates or adjusts signals exchanged between primary voltage domain 20 and secondary voltage domain 30 by shifting voltage levels to align with the respective operating ranges of each domain.

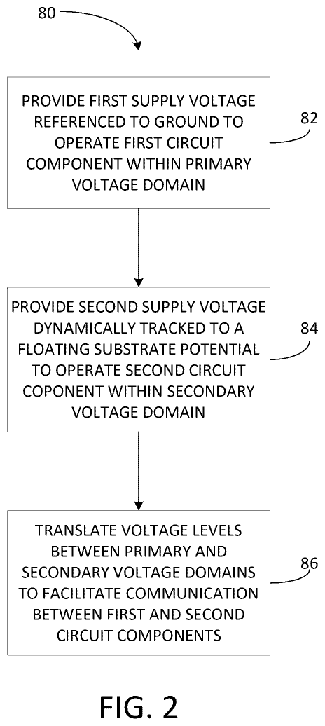

FIG. 2 is a flow diagram of a method 80 enabling circuit components to operate within and communicate across different voltage domains, according to aspects of this disclosure. In some examples, method 80 allows communication between a first circuit component such as digital core 26 operating within primary voltage domain 20 that is referenced to ground, and a second circuit component such as CMOS IP cell 32 operating within a secondary voltage domain 30 that is referenced to a floating substrate potential. In some examples, method 80 is implemented by voltage-level translation interface 40, which allows CMOS IP cell 32 to operate within secondary voltage domain 30 while maintaining compatibility with components such as digital core 26 in primary voltage domain 20.

In step 82, a first supply voltage (VDD) that is referenced to ground potential (VSS=0V) is provided to operate a first circuit component such as digital core 26 within primary voltage domain 20. In some examples, supply voltage VDD is generated by VDD regulator 25. In step 84, a second supply voltage (V_LDO) that is dynamically tracked to a floating substrate potential (VEE) is provided to operate a second circuit component such as CMOS IP cell 32 within a secondary voltage domain. The second supply voltage is dynamically tracked relative to the fluctuating substrate potential VEE to ensure that certain components such as NMOS transistors receive a supply voltage that remains stable despite variations in the substrate potential. In some examples, step 84 is implemented by substrate tracking regulator 52, which comprises bandgap circuit 100 and LDO regulator 300. In step 86, voltage levels are translated between the primary voltage domain 20 and secondary voltage domain 30 to allow communication between the first and second circuit components. In some examples, step 86 is carried out by voltage level translator 54 which shifts signal levels to align with the voltage ranges of the receiving domain.

FIG. 3 is a conceptual block diagram of an exemplary circuit architecture 50 illustrating dynamic voltage-level translation interface 40 in more detail, according to aspects of this disclosure. Voltage-level translation interface 40 implements method 80 of FIG. 2 to integrate CMOS circuit component (IP cell) 32 within secondary voltage domain 30 while maintaining compatibility with other circuit components such as digital core IP cell 26 operating in primary voltage domain 20. In FIG. 3, voltage-level translation interface 40 comprises substrate tracking regulator 52, which implements step 84 of method 80; and voltage-level translator 54, which implements step 86 of method 80.

Digital core circuit component 26, as described above, is a circuit component such as a standardized IP cell that may perform one or more defined functions that are repeatable across multiple ICs and applications, such as logic operations, memory storage, signal processing, power management, clock generation, timing control, and other functions. When operating within primary voltage domain 20, digital core circuit component 26 is powered by supply voltage VDD, which is regulated relative to ground (VSS) by VDD regulator 25. Specifically, VDD regulator 25 receives an input voltage (e.g., from a higher unregulated supply) and maintains a stable VDD output that is referenced to ground, ensuring reliable operation of digital core 26. The VDD pin of digital core 26 is connected to the VDD output of VDD regulator 25, while the VSS pin is tied directly to ground. This configuration allows digital core 26 to operate with a supply voltage VDD referenced to ground.

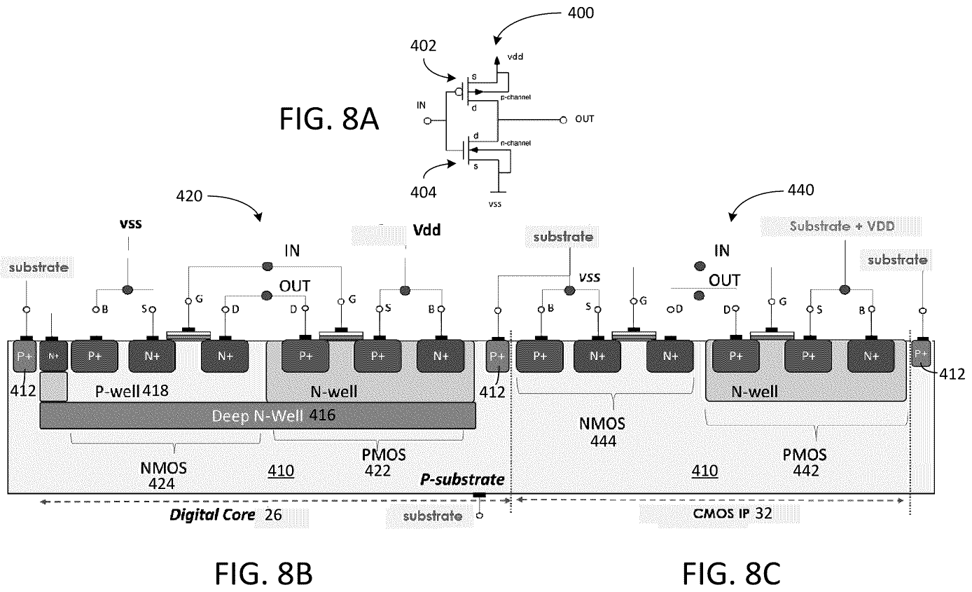

The substrate pin of digital core 26 is connected to the negatively or otherwise biased substrate to enable digital core 26 to function in an environment where the substrate potential is different from ground, so long as circuit elements such as transistors requiring ground-referenced operation are properly isolated using DNWELL techniques. In this approach, a localized P-well is formed within a DNWELL, enabling NMOS transistors within digital core 26 to be biased independently of the substrate potential. The implementation of DNWELL isolation within digital core 26 is illustrated in further detail in FIG. 8.

VDD regulator 25 generates a stable supply voltage VDD, referenced to ground (VSS=0V), for circuit components operating within primary voltage domain 20, including digital core 26 and voltage-level translator 54. As shown in FIG. 3, VDD regulator 25 regulates an input voltage (e.g., from an external power source) and outputs VDD at a well-defined potential relative to ground. The VDD output of VDD regulator 25 is directly connected to the VDD pins of digital core 26 and voltage-level translator 54, and the VSS pin of VDD regulator 25 is tied to ground to establish a fixed voltage reference for the regulator and the components it powers. The substrate pin of VDD regulator 25 is coupled to the substrate, which, in the case of secondary voltage domain 30, may be negatively biased. This configuration allows VDD regulator 25 to function in an environment where the substrate is not necessarily fixed to ground while still maintaining a stable ground-referenced VDD supply for components operating within primary voltage domain 20.

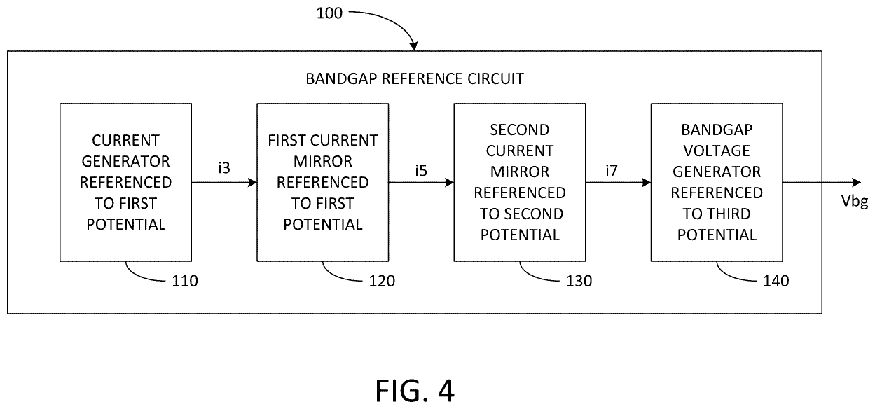

Substrate tracking regulator 52, which is described in more detail below with reference to FIGS. 4-7, is a subcomponent of voltage-level translation interface 40 that generates a supply voltage VREF (VDD for CMOS IP cell 32) that is dynamically referenced to the floating substrate potential VEE. By continuously tracking variations in the floating substrate potential and maintaining a stable VDD offset, substrate tracking regulator 52 ensures that CMOS circuit component 32 and other components within secondary voltage domain 30 operate as if they were in a ground-referenced environment, despite the substrate being at a non-zero or negative bias. The substrate pin of substrate tracking regulator 52 is connected to the floating substrate potential VEE, allowing it to follow substrate voltage fluctuations and regulate VDD accordingly. The VDD output pin of substrate tracking regulator 52 supplies a dynamically tracked VDD, such that circuit elements within secondary voltage domain 30 receive a stable operating voltage relative to their substrate-referenced environment.

CMOS circuit component 32 is a standardized circuit component such as an IP cell configured to operate within secondary voltage domain 30, where voltage references are defined relative to floating substrate potential VEE rather than ground. Unlike digital core 26, CMOS circuit component 32 does not require DNWELL isolation techniques or other design modifications to accommodate a negatively or otherwise biased substrate. Instead, CMOS circuit component 32 receives a supply voltage VDD from substrate tracking regulator 52 that is dynamically tracked to floating substrate potential VEE. The substrate pin and VSS pin of CMOS circuit component 32 are both directly connected to the floating substrate potential VEE, while the VDD pin is connected to the dynamically tracked voltage supply output (VEE+VDD) of substrate tracking regulator 52.

Voltage-level translator 54 comprises level shifters for translating signals between primary voltage domain 20 and secondary voltage domain 30, allowing bidirectional communication between components operating in primary voltage domain 20, such as digital core 26, and components operating in secondary voltage domain 30, such as CMOS circuit component 32. In circuit architecture 50 of FIG. 3, signals originating from digital core 26 in primary voltage domain 20 are translated downward in voltage to match the voltage levels of CMOS circuit component 32, while signals originating from CMOS circuit component 32 in secondary voltage domain 30 are translated upward in voltage to match the voltage levels of digital core 26. To accomplish this, voltage-level translator 54 is powered by two distinct supply voltages: VDD referenced to ground, supplied by VDD regulator 25, and VREF (which is equal to VDD in this example) dynamically tracked to the floating substrate potential VEE, supplied by substrate tracking regulator 52. The VSS pin of voltage-level translator 54 is connected to ground to maintain proper referencing for signals originating in primary voltage domain 20, while a second reference is taken from the floating substrate potential VEE to ensure proper referencing for signals originating in secondary voltage domain 30.

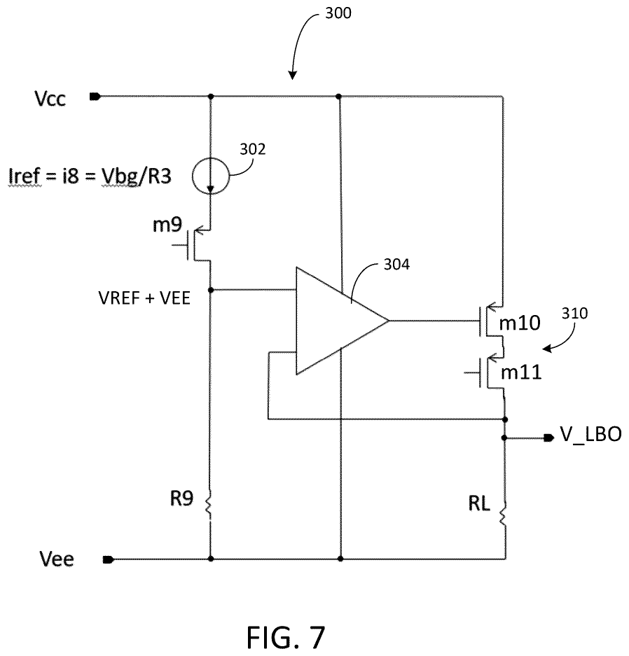

Substrate tracking regulator 52, described in detail with reference to FIGS. 4-7, generates a stable reference voltage VDD and regulates the supply voltage VDD relative to floating substrate potential VEE. To this end, substrate tracking regulator 52 comprises bandgap circuit 100 (FIGS. 4-6) that establishes a stable bandgap voltage Vbg independent of VEE, and low-dropout (LDO) regulator 300 (FIG. 7) that produces and regulates a supply voltage VREF (VDD) from the bandgap voltage Vbg that dynamically tracks VEE.

FIG. 4 is a conceptual block diagram of bandgap circuit 100, according to aspects of this disclosure. The term “bandgap” refers to the energy gap between the valence and conduction bands in semiconductors, which is nearly constant over a wide range of temperatures. Bandgap circuit 100 produces a constant bandgap voltage regardless of temperature changes or power supply variations. The bandgap voltage is typically around 1.25V, approximately equal to the bandgap voltage of silicon. Bandgap circuit 100 comprises current generator 110, first current mirror 120, second current mirror 130, and bandgap voltage generator 140. Bandgap circuit 100 generates a stable bandgap voltage Vbg. In one example, bandgap circuit 100 may be configured on an IC in a hard disk drive (HDD), such as in the preamplifier, spindle motor control circuitry, or other components of the HDD.

Current generator 110 operates with respect to a first potential, which in some implementations is a negative bias potential (VEE) applied to the IC substrate. This first potential serves as the reference for current generation, ensuring stability in circuits operating at varying substrate biases. In one non-limiting embodiment, for example, VEE may be −3V. This is merely one example of a first potential that current generator 110 may be referenced to; current generator 110 may be referenced to other potentials as appropriate to a particular application. Current generator 110 generates a first current i3 that has a negative temperature-dependent voltage component and a positive temperature-dependent voltage component.

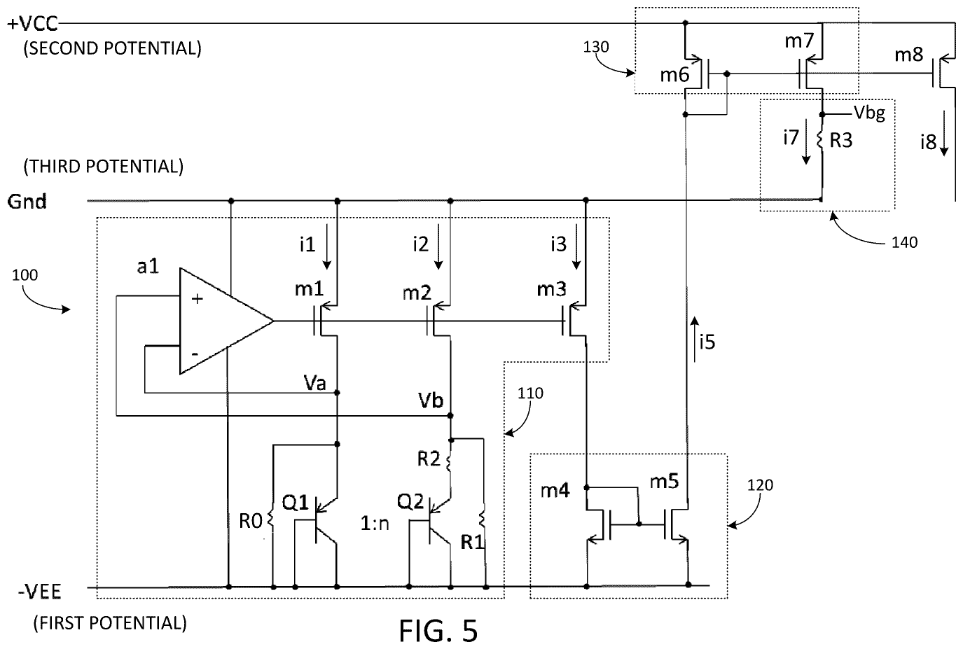

First current mirror 120 is also referenced to the first potential and receives first current i3 from current generator 110. As mentioned above, while the first potential is depicted in FIG. 5 as the bias potential VEE of the substrate of the IC on which bandgap reference circuit 100 is formed, the first potential may be any other potential as is appropriate to the application. First current mirror 120 replicates first current i3, producing second current i5 while maintaining the same reference to the first potential VEE. This ensures consistency in current flow despite fluctuations in substrate potential.

Second current mirror 130 is referenced to a second potential and receives second current i5 from first current mirror 120. In one non-limiting example, the second potential is a positive supply potential such as VCC as depicted in FIG. 5. Common supply potentials in HDDs for example, and for non-limiting purposes of illustration, include 5V and 12V. These are merely examples of a second potential that second current mirror 130 may be referenced to; second current mirror 130 may be referenced to other potentials as is appropriate to the application. Second current mirror 130 generates third current i7 that is equal to second current i5 generated by first current mirror 120.

Bandgap voltage generator 140, referenced to a third potential (e.g., ground), receives third current i7 from second current mirror 130 and generates bandgap voltage Vbg. Bandgap voltage Vbg remains independent of substrate fluctuations, providing a reliable reference for downstream regulation. In one non-limiting example, the third voltage level is ground (VSS=0V). This is merely one example of a third potential that bandgap voltage generator 140 may be referenced to; bandgap voltage generator 140 may be referenced to other potentials as is appropriate to the application.

FIG. 5 is a more detailed diagram of bandgap circuit 100, according to aspects of this disclosure. As can be seen in FIG. 5, current generator 110 of bandgap circuit 100 is referenced to a first potential VEE (in one example, a negatively biased substrate) and comprises operational amplifier a1; first, second and third PMOS transistors m1, m2, and m3; first and second PNP bipolar junction transistors Q1 and Q2; and first, second and third resistors R0, R1, and R2. First current mirror 120 is also referenced to the first potential and comprises first and second NMOS transistors m4 and m5. Second current mirror 130 is referenced to a second potential (in one example, positive supply potential VCC) and comprises fourth and fifth PMOS transistors m6 and m7. Bandgap voltage generator 140 is referenced to a third potential (in one example, ground) and comprises fourth resistor R3.

In current generator 110, the positive power supply terminal of operational amplifier a1 is coupled to the third potential (in one example, ground), and the negative supply terminal of amplifier a1 is coupled to the first potential (in one example, the negatively biased substrate). The non-inverting input terminal of amplifier a1 is coupled to the drain of second PMOS transistor m2, which is at voltage Vb, and to second and third resistors R1 and R2. The inverting input terminal of amplifier a1 is coupled to the drain of first PMOS transistor m1, which is at voltage Va, to first resistor R0, and to the emitter of first PNP transistor Q1. The output terminal of amplifier a1 is coupled to the gates of first, second and third PMOS transistors m1, m2 and m3.

Current i1 flows into the source of first PMOS transistor m1, which is coupled to the third potential (in one example, ground). The gate of first PMOS transistor m1 is coupled to the output terminal of operational amplifier a1 and to the gates of second and third PMOS transistors m2 and m3. The drain of first PMOS transistor m1, which is at voltage Va, is coupled to the inverting input of amplifier a1, to first resistor R0, and to the emitter of first PNP transistor Q1.

Current i2 flows into the source of second PMOS transistor m2, which is coupled to the third potential (in one example, ground). The gate of second PMOS transistor m2 is coupled to the output terminal of amplifier a1 and to the gates of first and third PMOS transistors m1 and m3. The drain of second PMOS transistor m2, which is at voltage Vb, is coupled to the non-inverting input of operational amplifier a1, and to second and third resistors R1 and R2.

Current i3 (the “first current”) flows into the source of third PMOS transistor m3, which is coupled to the third potential (in one example, ground). The gate of third PMOS transistor m3 is coupled to the output terminal of amplifier a1 and to the gates of first and second PMOS transistors m1 and m2. The drain of third PMOS transistor m3 is coupled to first current mirror 120, in particular, to the drain of first NMOS transistor m4 and to the gates of first and second NMOS transistors m4 and m5.

On end of first resistor R0 is coupled to the drain of first PMOS transistor m1, which is at voltage Va, to the inverting input of amplifier a1, and to the emitter of first PNP transistor Q1. The other end of first resistor R0 is coupled to the first potential (in one example, the negatively biased substrate). As can be seen in FIG. 5, resistor R0 is connected in parallel with first PNP transistor Q1. In one example, first resistor R0 has the same resistance value as second resistor R1, that is, R0=R1.

The emitter of first PNP transistor Q1 is coupled to the drain of first PMOS transistor m1, which is at voltage Va, to the inverting input of amplifier a1, and to one end of first resistor R0. The base and collector of first PNP transistor Q1 are coupled to the first potential (in one example, the negatively biased substrate). The emitter of second PNP transistor Q2 is coupled to third resistor R2. The base and collector of PNP transistor Q2 are coupled to the first potential (in one example, the negatively biased substrate). The ratio of the number of Q1 PNP transistors to the number of Q2 PNP transistors is 1:n. In the example of bandgap reference circuit 100, there is one Q2 transistor and one Q1 transistor. Thus n=1. In another example (not illustrated), if there were 3 Q1 transistors and 27 Q2 transistors, n=9.

One end of second resistor R1 is coupled to the drain of second PMOS transistor m2, which is at voltage Vb, to the non-inverting input of amplifier a1 and to third resistor R2. The other end of second resistor R1 is coupled to the first potential (in one example, the negatively biased substrate). One end of third resistor R2 is coupled to the drain of second PMOS transistor m2, which is at voltage Vb, to the non-inverting input of amplifier a1, and to one end of second resistor R1. The other end of third resistor R2 is coupled to the emitter of second PNP transistor Q2. As can be seen in FIG. 5, third resistor R2 and second PNP transistor Q2 are connected in series, and second resistor R1 is connected in parallel with the series connection of third resistor R2 and second PNP transistor Q2.

In operation of current generator 110, amplifier a1 forces Va (the drain voltage of first PMOS transistor m1) to be equal to Vb (the drain voltage of second PMOS transistor m2). This is known as a “virtual short” or “virtual ground” effect because the differential inputs have the same voltage even though they are not connected. Amplifier a1 amplifies the difference between voltages Va and Vb applied to its input terminals. Amplifier a1 is configured in a negative feedback configuration in which its output is fed back to its inverting input via the gate control of first PMOS transistor m1. At the same time, the non-inverting input of amplifier a1 is coupled to the drain voltage Vb of second PMOS transistor m2.

If voltage Va (the drain voltage of first PMOS transistor m1 and inverting input to amplifier a1) were to rise above voltage Vb (the drain voltage of second PMOS transistor m2 and the non-inverting input to amplifier a1), the output of amplifier a1 would decrease. This reduction in output voltage would reduce the gate voltage of first PMOS transistor m1, causing it to reduce its conduction and thereby bring voltage Va back down towards voltage Vb. Conversely, if voltage Va were to fall below voltage Vb, the output of amplifier a1 would increase. This increase in output voltage would increase the gate voltage of first PMOS transistor m1, causing it to increase its conduction and thereby bring voltage Va back up towards voltage Vb. In this way, amplifier a1 forces Va to be equal to Vb by adjusting its output in response to the difference between Va and Vb, which in turn controls the conduction of first PMOS transistor m1 to balance voltages Va and Vb.

In MOSFETs such as PMOS transistors m1, m2, and m3, the current flowing from the source to the drain (i1, i2, i3) is largely determined by the voltage difference between the gate and the source (the gate-source voltage). In circuit 100, because PMOS transistors m1, m2, and m3 all have their sources connected to the third potential (in one example, ground) and their gates connected to the same voltage (output of amplifier a1), PMOS transistors m1, m2, and m3 will all have the same gate-source voltage. Because PMOS transistors m1, m2, and m3 have the same gate-source voltage (and assuming transistors m1, m2, and m3 are identical and operating in saturation), currents i1, i2, and i3 respectively flowing into PMOS transistors m1, m2, and m3 are equal. That is,

i1=i2=i3.

Both the base and collector of first PNP transistor Q1 are tied to the first potential (in one example, the negatively biased substrate). Thus, voltage Va (the drain voltage of first PMOS transistor m1 and the emitter voltage of first PNP transistor Q1) is equal to the base-emitter voltage of first PNP transistor Q1 (Vbe). As previously described, Vb=Va, so Vb=Va=Vbe. Both the base and collector of second PNP transistor Q2 are also tied to the first potential. Thus, the voltage across third resistor R2 is Vb−Vbe2=Vbe−Vbe2=AVbe. Current i2 is equal to the current flowing through third resistor

$$R 2 ( \frac{ΔV be}{R 2} )$$

plus the current flowing through second resistor,

$$R 1 ( \frac{V be}{R 1} )$$

where Vb=Vbe, so

$${i}_{2} = \frac{{V}_{be}}{{R}_{1}} + \frac{{ΔV}_{be}}{{R}_{2}} .$$

Current i3 (the “first current”) is the current flowing from current generator 110 to first current mirror 120. Since i1=i2=i3, current generator 110 is referenced to the first potential (in one example, the negatively biased substrate) and produces an output current i3 (the “first current”) that may be characterized as:

$${i}_{3} = \frac{{V}_{be}}{{R}_{1}} + \frac{{ΔV}_{be}}{{R}_{2}} .$$

The base-emitter voltage (Vbe) of a BJT decreases as temperature increases (a negative temperature coefficient), whereas the voltage difference of the base-emitter voltages of two BJTs operating at different current densities (ΔVbe) increases as temperature increases (a positive temperature coefficient). Thus, the current i3 generated by current generator 110 (the “first current”) may also be characterized as a current that is referenced to the first potential (in one example, the negatively biased substrate) and that has both a negative temperature-dependent voltage component and a positive temperature-dependent voltage component.

In first current mirror 120, the drain of first NMOS transistor m4 is coupled to the drain of third PMOS transistor m3, and therefore also to the current i3 (the “first current”) flowing out from third PMOS transistor m3. The drain of first NMOS transistor m4 is also coupled to the gates of first and second NMOS transistors m4 and m5 (which are tied together). The sources of first and second NMOS transistors m4 and m5 are coupled to the first potential (in one example, the negatively biased substrate). The drain of second NMOS transistor m5 is coupled to second current mirror 130, in particular, to the drain of fourth PMOS transistor m6 and to the gates of fourth and fifth PMOS transistors m6 and m7 (which are tied together).

First current mirror 120, implemented using NMOS transistors m4 and m5, ensures that current i3 is accurately replicated as i5 within the same voltage domain (VEE). Similarly, second current mirror 130, implemented using PMOS transistors m6 and m7, transfers i5 into a higher voltage domain (VCC) while maintaining current equality (i7=i5=i3). Current i3 (the “first current”) flowing through third PMOS transistor m3 also flows through first NMOS transistor m4 due to the gate and drain of first NMOS transistor m4 being tied together (forming what's known as a diode-connected transistor). This sets a certain gate-source voltage for first NMOS transistor m4, which is also applied to second NMOS transistor m5 since the gates of NMOS transistors m4 and m5 are tied. Because the gate-source voltages of first and second NMOS transistors m4 and m5 are the same, the drain current i5 in second NMOS transistor m5 (the “second current”) will be equal to the drain current i3 in first NMOS transistor m4 (the “first current”), that is, i5=i3. In sum, the drain current i3 of third PMOS transistor m3 (the “first current”) is mirrored by first and second NMOS transistors m4 and m5, which are referenced to the first potential (in one example, the negatively biased substrate), and then bounced to second current mirror 130, which is referenced to the second potential (in one example, a positive supply potential).

In second current mirror 130, the drain of fourth PMOS transistor m6 is coupled to the drain of second NMOS transistor m5, and therefore also to the current i5 flowing out from second NMOS transistor m5 (the “second current”). The drain of fourth PMOS transistor m6 is also coupled to the gates of fourth and fifth PMOS transistors m6 and m7 (which are tied together). The sources of PMOS transistors m6 and m7 are tied to the second potential (in one example, a positive supply potential). The drain of fifth PMOS transistor m7 is coupled to bandgap voltage generator 140.

Fourth and fifth PMOS transistors m6 and m7 are configured as a current mirror, with their gates tied together and to the drains of fourth PMOS transistor m6 and second NMOS transistor m5. The current i5 flowing from second NMOS transistor m5 (the “second current”) also flows through fourth PMOS transistor m6 due to the gate and drain of PMOS transistor m6 being tied together (forming a diode-connected transistor). This sets a certain gate-source voltage for fourth PMOS transistor m6, which is also applied to fifth PMOS transistor m7 since the gates of PMOS transistors m6 and m7 are tied. Because the gate-source voltages of fourth and fifth PMOS transistors m6 and m7 are the same, the drain current i7 in fifth PMOS transistor m7 (the “third current”) will be equal to the drain current i5 in fourth PMOS transistor m6 (the “second current”). Drain current i7 of fifth PMOS transistor m7 is coupled to reference voltage generator 140. Thus, the second current i5, which is equal to the first current i3, is effectively mirrored into fifth PMOS transistor m7 from second NMOS transistor m5 via fourth PMOS transistor m6, or i7=i5=i3.

Bandgap voltage generator 140 comprises fourth resistor R3 coupled at one end to the output of second current mirror 130 (i.e., to the drain current i7 of fifth PMOS transistor m7) and at its other end to the third potential (in one example, ground). Bandgap voltage Vbg is generated by applying i7 (the “third current”) across fourth resistor R3. Therefore, bandgap voltage Vbg is referenced to the third potential (in one example, ground) and is equal to i3 multiplied by R3 (i7=i5=i3).

V_{bg}=i₃R₃

$${V}_{bg} = ( \frac{{V}_{be}}{{R}_{1}} + \frac{{ΔV}_{be}}{{R}_{2}} ) ( {R}_{3} )$$

$${V}_{bg} = ( \frac{{R}_{3}}{{R}_{1}} ) ( {V}_{be} ) + ( \frac{{R}_{3}}{{R}_{2}} ) ( {ΔV}_{be} )$$

The above equation is in the form of a bandgap equation, with one term representing a voltage component that decreases with increased temperature and the other term representing a voltage component that increases with increased temperature. Here, Vbe is the base-emitter voltage of PNP bipolar junction transistor Q1 which decreases with an increase in temperature (negative temperature coefficient), and ΔVbe is the difference between the base-emitter voltages of PNP transistors Q1 and Q2, which increases with an increase in temperature (positive temperature coefficient). The combination of these two effects cancels out the temperature-dependent components and allows generation of a bandgap voltage Vbg that is stable and constant over a wide range of temperatures by selecting values for R1, R2 and R3.

In sum, the third current i7 is equal to the first current i3, but whereas the first current i3 flows from the third potential (in one example, ground) to the first potential (in one example, the negatively biased substrate), the third current i7 flows from the second potential (in one example, the positive supply potential) to the third potential (in one example, ground). Stated another way, the third current i7 and the first current i3 are equal, but whereas the third current i7 is referenced to ground, the first current i3 is referenced to the negatively biased substrate potential. The third current i7 is applied across resistor R3, generating a stable bandgap voltage Vbg. By carefully selecting R3 and the transistor ratios, the bandgap voltage Vbg remains independent of temperature variations and is consistently referenced to ground.

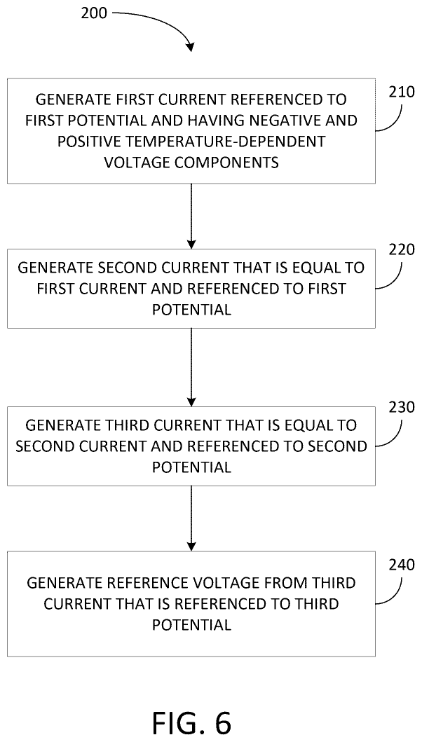

FIG. 6 is a flow diagram of a method 200 for generating bandgap voltage Vbg, according to aspects of this disclosure. Step 210 involves generating first current i3, referenced to the floating substrate (VEE). This current contains both negative and positive temperature-dependent voltage components, ensuring stable operation across temperature variations. In particular, the first current has a negative temperature-dependent voltage component

$$( \frac{V be}{R 1} )$$

and a positive temperature-dependent voltage component

$$( \frac{ΔV be}{R 2} )$$

such that

$${i}_{3} = \frac{{V}_{be}}{{R}_{1}} + \frac{{ΔV}_{be}}{{R}_{2}} .$$

In one example, the first current i3 is generated by current generator 110 of bandgap circuit 100 which comprises operational amplifier a1; first, second, and third PMOS transistors m1, m2, and m3; first and second PNP bipolar junction transistors Q1 and Q2; and first, second, and third resistors R0, R1, and R2 (R1=R0), configured as described above.

In step 220, a second current i5 is generated that is equal to the first current i3 and referenced to the first potential (in one example, the negatively biased substrate). In particular, the first current i3 is coupled to first current mirror 120 that is referenced to the first potential (in one example, the negatively biased substrate) to generate the second current i5. In one example, first current mirror 120 comprises first and second NMOS transistors m4 and m5, configured as described above.

In step 230, a third current i7 is generated that is equal to the second current i5 and referenced to the second potential (in one example, the positive supply potential). In particular, the second current i5 is coupled to second current mirror 130 that is referenced to the second potential (in one example, the positive supply potential) to generate the third current i7. In one example, second current mirror 130 comprises fourth and fifth PMOS transistors m6 and m7, configured as described above.

In step 240, a bandgap voltage Vbg that is referenced to the third potential (in one example, ground) is generated from the third current i7. In one example, bandgap voltage generator 140 comprises fourth resistor R3 coupled between second current mirror 130 and the third potential (in one example, ground). Applying current i7 across resistor R3 results in generation of a bandgap voltage Vbg that is referenced to the third potential (ground). Therefore, Vbg is referenced to the third potential (ground) and is equal to i3 multiplied by R3 (i7=i5=i3):

V_{bg}=i₃R₃

$${V}_{bg} = ( \frac{{V}_{be}}{{R}_{1}} + \frac{{ΔV}_{be}}{{R}_{2}} ) ( {R}_{3} )$$

$${V}_{bg} = ( \frac{{R}_{3}}{{R}_{1}} ) ( {V}_{be} ) + ( \frac{{R}_{3}}{{R}_{2}} ) ( {ΔV}_{be} )$$

For proper operation of LDO regulator 300, bandgap circuit 100 generates a stable reference current i8 from the bandgap voltage Vbg. To this end, PMOS transistor m8 is configured as a current mirror in conjunction with PMOS transistor m7. As can be seen in FIG. 5, the gate of transistor m8 is coupled to the gates of transistors m6 and m7, the source of m8 is tied to the second potential (in one example, positive supply potential VCC), and the drain of transistor m8 is coupled to supply reference current i8 to LDO regulator 300. Because m7 and m8 are matched devices operating in saturation, the drain current i8 of transistor m8 is a mirrored version of the current i7 flowing through transistor m7. Thus, reference current i8 that is supplied to LDO regulator 300 can be expressed as follows:

$${i}_{8} = {i}_{7} = \frac{{V}_{bg}}{{R}_{3}}$$

This expression shows that reference current i8 is directly determined by bandgap voltage Vbg and resistor R3. Because Vbg is stable and temperature independent, reference current i8 maintains the same stability and temperature independence, such that LDO regulator 300 can produce a precisely regulated output voltage.

FIG. 7 is a circuit diagram of LDO regulator 300, which together with bandgap circuit 100 comprises substrate tracking regulator 52, in accordance with aspects of this disclosure. LDO regulator 300 generates a dynamically tracked supply voltage that maintains a stable offset from floating substrate potential VEE. Because VEE is not fixed to ground and may vary dynamically, it is necessary to establish a stable reference voltage independent of VEE. LDO regulator 300 achieves this using bandgap voltage Vbg and reference current i8, both of which are derived from bandgap circuit 100.

LDO regulator 300 receives reference current i8 from bandgap circuit 100 and uses it to establish reference VREF that is referenced to non-zero substrate potential VEE. In circuit architecture 50 of FIG. 3, this reference voltage VREF serves as the supply voltage VDD for CMOS IP cell 32, such that VREF=VDD. However, VREF is a more general term, as its exact value depends on the resistor ratio used in substrate tracking regulator 52. Reference current i8 is represented in FIG. 7 as current source 302, and as described above can be expressed as:

$${i}_{8} = \frac{{V}_{bg}}{{R}_{3}}$$

where Vbg is the bandgap voltage generated by bandgap circuit 100, and R3 is the resistor in circuit 100 (FIG. 5) that references the bandgap voltage to ground. Cascode transistor m9 provides overvoltage protection and acts as a buffer between the reference current source and resistor R9, ensuring that the voltage at the drain of transistor m9 remains stable. Resistor R9 is connected between the drain of cascode transistor m9 and substrate potential VEE. Reference current i8 flows through resistor R9, establishing a stable voltage drop VREF across resistor R9 that is given by:

$${V}_{REF} = {i}_{8} {R}_{9} = {V}_{bg} \frac{{R}_{9}}{{R}_{3}}$$

Since resistor R9 is referenced to VEE, the regulated output voltage V_LDO of LDO regulator 300 is given by:

$${V}_{LDO} = {V}_{EE} + {V}_{REF} = {V}_{EE} + {V}_{bg} \frac{{R}_{9}}{{R}_{3}}$$

Thus, V_LDO is precisely offset from VEE by VREF, where VREF is determined by the ratio R9/R3 and the bandgap voltage Vbg. Because bandgap voltage Vbg is highly stable, V_LDO remains a well-regulated voltage despite fluctuations in VEE. For example, where Vbg=1.225V, R9=65.4kΩ, and R3=100 kΩ, the resulting output voltage is

V_LDO=VEE+0.801V.

LDO regulator 300 further comprises high-gain amplifier 304, which enforces precise regulation of V_LDO. Amplifier 304 is configured in a negative feedback loop, ensuring that V_LDO dynamically tracks VEE+VREF. The inverting input of amplifier 304 is tied to VEE+VREF (the sum of the substrate potential VEE and the voltage drop VREF across resistor R9), while its non-inverting input is tied to the LDO output voltage V_LDO. Because amplifier 304 operates in a high-gain configuration, it forces V_LDO to track VEE+VREF by dynamically adjusting the conduction of PMOS output stage 310. Specifically, amplifier 304 controls the gate voltage of pass transistor m10 to regulate its conduction and maintain the desired output voltage. By enforcing equality between its input terminals, amplifier 304 ensures that:

V_LDO=VEE+VREF

Thus, V_LDO is actively regulated to be offset by VREF from substrate potential VEE, where the offset VREF is determined by Vbg (R9/R3).

PMOS output stage 310 regulates output voltage V_LDO to be stable across variations in load current and substrate potential. Output stage 310 comprises pass transistor m10, whose gate is controlled by amplifier 304 to dynamically regulate V_LDO, and cascode transistor m11, which isolates pass transistor m10 from load transients and voltage fluctuations at the output node. The effective load resistance connected to LDO regulator 300 is modeled by load resistor RL, which in the context of FIG. 3 represents the input resistance of CMOS IP cell 32. Since CMOS IP cell 32 operates in secondary voltage domain 30, its operational supply voltage is V_LDO=VEE+VDD, where

$$V DD = V REF = {V}_{bg} \frac{{R}_{9}}{{R}_{3}} .$$

FIGS. 8A-8C illustrate the principles of this disclosure by comparing two integrated circuit (IC) layouts of a standard CMOS inverter circuit 400 (FIG. 8A): a first IC layout 420 (FIG. 8B) that utilizes conventional DNWELL isolation techniques; and a second IC layout 440 (FIG. 8C) that operates in conjunction with voltage level translation interface 40 to eliminate the need for DNWELL isolation, according to aspects of this disclosure.

FIG. 8A is a circuit diagram of an exemplary CMOS inverter circuit 400 comprising PMOS transistor 402 and NMOS transistor 404 connected in series between supply voltage VDD and reference potential VSS. An input signal (VIN) is applied to the shared gate connection of transistors 402 and 404, while an output signal (VOUT) is taken from the shared drain connection of transistors 402 and 404. When VIN is low, PMOS transistor 402 is in a conducting state, connecting the output to supply voltage VDD and producing a high output (VOUT=VDD). Conversely, when VIN is high, NMOS transistor 404 conducts, pulling the output to the reference potential VSS and producing a low output (VOUT=VSS).

FIG. 8B is a conceptual IC layout of an inverter 420 corresponding to inverter circuit 400 of FIG. 8A, as implemented within digital core 26 (FIG. 3) using DNWELL isolation techniques. DNWELL isolation ensures proper operation of NMOS transistors within digital core 26, such as NMOS transistor 424, when digital core 26 operates within an environment referenced to a negatively or non-zero biased substrate 410. Inverter 420 operates between a fixed supply voltage VDD, provided by VDD regulator 25 (FIG. 3), and reference potential VSS. Inverter 420 is fabricated within DNWELL structure 416, which forms an electrically isolated P-well region 418 that may be biased to provide a ground reference for the source and bulk (“b”) connections of NMOS transistor 424. The source and bulk connections of PMOS transistor 422 are coupled to VDD, as supplied by VDD regulator 25. An input signal (VIN) is applied to the shared gate connection of transistors 422 and 424, while the output signal (VOUT) is taken from their shared drain connection. To enable digital core 26 to function within the negatively biased environment defined by substrate 410, the substrate pin of digital core 26 is connected to non-zero biased substrate 410 via guard ring 412.

FIG. 8C is a conceptual IC layout of an inverter 440, corresponding to inverter circuit 400 of FIG. 8A, as implemented within CMOS circuit component (FIG. 3) using voltage level translation interface 40 rather than DNWELL isolation techniques. Unlike the implementation shown in FIG. 8B, CMOS circuit component 32 operates in secondary voltage domain 30 where voltages are referenced to floating substrate potential VEE rather than ground. Consequently, PMOS transistor 442 and NMOS transistor 444 are configured to operate within this dynamically tracked voltage domain without requiring DNWELL isolation. Inverter 440 operates with respect to a supply voltage VDD that is dynamically tracked by substrate tracking regulator 52 to floating substrate potential VEE. Instead of being enclosed within DNWELL structure 416, inverter 440 is integrated directly into substrate 410, which serves as the reference potential for NMOS transistor 444. The need for an isolated P-well region is reduced or eliminated since the entire CMOS circuit component 32 functions relative to VEE.

The source and bulk connections of NMOS transistor 444 are tied directly to the floating substrate potential VEE via the connection of the VSS and substrate pins of CMOS IP cell 32 to substrate 410 via guard ring 412. Meanwhile, the source and bulk connections of PMOS transistor 442 are coupled to the supply voltage V_LDO=VEE+VREF (VREF=VDD) provided by substrate tracking regulator 52. An input signal VIN is applied to the shared gate connection of transistors 442 and 444, while the output signal VOUT is taken from their shared drain connection.

The systems and circuits disclosed herein may be implemented using control circuitry that may be partially or wholly implemented in one or more processing devices such as an application-specific integrated circuit (ASIC), a field-programmable gate array (FPGA), a system-on-a-chip (SoC), or other suitable semiconductor devices. The control circuitry may include digital logic, state machine circuitry, or mixed-signal circuits configured to perform voltage-level translation, substrate voltage tracking, and other operations described herein. The control circuitry may further include processing logic, such as a microcontroller or processor executing instructions stored in a computer-readable medium, such as a non-volatile semiconductor memory device integrated within or external to the processing logic.

One or more processing devices may comprise the control circuitry and may perform, individually and/or collectively, some or all of the functions of the control circuitry. Such processing devices may be part of or integrated within semiconductor devices implementing voltage translation and substrate voltage regulation circuits. In some implementations, such processing devices may be part of a larger integrated system, including HDD control circuitry, memory controllers, sensor interfaces, or data processing subsystems. The systems and circuits described herein may be implemented in standalone semiconductor components, embedded within larger mixed-signal integrated circuits, or utilized in data storage systems, sensor arrays, industrial control systems, or other electronic devices requiring compatibility between multiple voltage domains.

While certain embodiments are described herein, these embodiments are presented by way of example only and do not limit the scope of this disclosure. Various omissions, substitutions, and modifications may be made without departing from the scope of this disclosure. The circuits and systems described herein are not limited to any particular implementation and may be used independently or in combination with other designs. Some system components or process steps may be omitted, modified, or reordered in some implementations. Nothing in this description implies that any particular feature, component, characteristic, or step is necessary or indispensable. Many variations, modifications, additions, and improvements are possible and fall within the scope of this disclosure as defined by the following claims.

1. A method for enabling circuit components to operate within and communicate across different voltage domains, comprising:
providing a first supply voltage referenced to ground to operate a first circuit component within a primary voltage domain;
providing a second supply voltage that is dynamically tracked relative to a floating substrate potential to operate a second circuit component within a secondary voltage domain; and
translating voltage levels between the primary voltage domain and the secondary voltage domain to facilitate communication between the first circuit component and the second circuit component.

2. The method of claim 1, wherein providing the second supply voltage comprises generating a bandgap voltage independent of the floating substrate potential using a bandgap circuit.

3. The method of claim 2, wherein providing the second supply voltage further comprises regulating the second supply voltage using a low dropout (LDO) regulator.

4. The method of claim 3, wherein the second supply voltage is VEE+VREF, the floating substrate potential is VEE, VREF is a reference voltage given by VREF=Vbg*(R9/R3), Vbg is the bandgap voltage, R3 is a resistor within the bandgap circuit that references the bandgap voltage Vbg to ground, and R9 is a resistor within the LDO regulator that references the reference voltage VREF to the floating substrate potential VEE.

5. The method of claim 2, wherein generating the bandgap voltage comprises generating a first current referenced to the floating substrate potential, the first current having a negative temperature-dependent voltage component and a positive temperature-dependent voltage component;
generating a second current that is equal to the first current and that is referenced to the floating substrate potential;
generating a third current that is equal to the second current and that is referenced to a voltage at least as high as the first supply voltage; and
generating the bandgap voltage from the third current that is referenced to ground.

6. The method of claim 3, wherein regulating the second supply voltage further comprises controlling an output pass transistor using a high gain amplifier in a negative feedback configuration to maintain the second supply voltage at a stable offset from the floating substrate potential.

7. The method of claim 6, wherein regulating the second supply voltage further comprises isolating the output pass transistor from load transients and variations in the floating substrate potential using a cascode transistor.

8. The method of claim 1, wherein the second circuit component is an intellectual property (IP) cell comprising CMOS devices.

9. A dynamic voltage level translation interface for enabling a second circuit component to operate within a secondary voltage domain referenced to a floating substrate potential and to communicate with a first circuit component operating within a primary voltage domain referenced to ground potential, comprising:
a substrate tracking regulator configured to generate a supply voltage that is dynamically tracked relative to the floating substrate potential and that is supplied to the second circuit component; and
a voltage level translator configured to shift voltage levels from the secondary voltage domain to the primary voltage domain to enable the second circuit component to communicate with the first circuit component.

10. The dynamic voltage level translation interface of claim 9, wherein the substrate tracking regulator comprises a bandgap circuit configured to generate a bandgap voltage independent of the floating substrate potential.

11. The dynamic voltage level translation interface of claim 10, wherein the substrate tracking regulator further comprises a low-dropout (LDO) regulator configured to regulate the supply voltage at a stable offset from the floating substrate potential.

12. The dynamic voltage level translation interface of claim 11, wherein the supply voltage is given by VLDO=VEE+VREF; VEE is the floating substrate potential; VREF is the stable offset where VREF=Vbg*(R9/R3); Vbg is the bandgap voltage generated by the bandgap circuit; R3 is a resistor within the bandgap circuit that references Vbg to ground; and R9 is a resistor within the LDO regulator that references the supply voltage to the floating substrate potential.

13. The dynamic voltage level translation interface of claim 11, wherein the LDO regulator further comprises a high gain amplifier configured in a negative feedback configuration that controls an output pass transistor to maintain the stable offset relative to the floating substrate potential.

14. The dynamic voltage level translation interface of claim 13, wherein the LDO regulator further comprises a first cascode transistor that isolates the LDO regulator from the bandgap circuit.

15. The dynamic voltage level translation interface of claim 14, wherein the LDO regulator further comprises a second cascode transistor that isolates the generated supply voltage from load transients and floating substrate potential variations.

16. An integrated circuit comprising:
a first circuit component operating within a primary voltage domain referenced to ground;
a second circuit component operating within a secondary voltage domain referenced to a floating substrate potential;
a substrate tracking regulator configured to generate a supply voltage dynamically tracked relative to the floating substrate potential to power the second circuit component; and
a voltage level translation interface configured to translate voltage levels between the primary voltage domain and the secondary voltage domain.

17. The integrated circuit of claim 16, wherein the substrate tracking regulator comprises a bandgap circuit configured to generate a bandgap voltage independent of the floating substrate potential.

18. The integrated circuit of claim 17, wherein the substrate tracking regulator further comprises a low-dropout (LDO) regulator configured to regulate the supply voltage at a stable offset from the floating substrate potential.

19. The integrated circuit of claim 18, wherein the supply voltage is given by VLDO=VEE+VREF; VEE is the floating substrate potential; VREF is the stable offset where VREF=Vbg*(R9/R3); Vbg is the bandgap voltage generated by the bandgap circuit; R3 is a resistor within the bandgap circuit that references Vbg to ground; and R9 is a resistor within the LDO regulator that references the supply voltage to the floating substrate potential.

20. The integrated circuit of claim 18, wherein the LDO regulator further comprises a high gain amplifier configured in a negative feedback configuration that controls an output pass transistor to maintain the stable offset relative to the floating substrate potential.
